(19) United States
(12) Patent Application Publication
(10) Pub. No.: US 2026/0033350 A1
(43) Pub. Date: Jan. 29, 2026

(54) SEMICONDUCTOR ARRANGEMENT, SYSTEM AND MANUFACTURING METHOD

(71) Applicant: Infineon Technologies Austria AG, Villach (AT)

(72) Inventors: Edward Fürgut, Dasing (DE); Thai Kee Gan, Melaka Tengah (MY); Robert Rösner, Oberschleißheim (DE); Julian Treu, München (DE)

(21) Appl. No.: 19/269,133

(22) Filed: Jul. 15, 2025

(30) Foreign Application Priority Data
Jul. 24, 2024 (DE) 102024206967.1

(51) Int. Cl. H01L 23/495; H01L 21/48; H01L 21/56; H01L 23/00; H01L 23/31; H01L 25/11; H10D 80/20

(52) U.S. Cl. CPC H01L 23/49562; H01L 21/4825; H01L 25/115; H10D 80/251; H01L 21/56; H01L 23/3107; H01L 24/32; H01L 24/48; H01L 24/73; H01L 2224/32245; H01L 2224/48245; H01L 2224/73265; H01L 2924/1033; H01L 2924/13064

(57) ABSTRACT

A semiconductor arrangement includes first and second semiconductor packages separate from one another. Each semiconductor package includes a die carrier having opposite first and second main faces, a transistor die disposed on the first main face, a first lead connected to a first load electrode of the transistor die, a second lead connected to a gate electrode of the transistor die, and an encapsulant embedding at least part of the first main face of the die carrier, inner portions of the leads and the transistor die. The first lead of the first semiconductor package is electrically connected to the first lead of the second semiconductor package, forming a source-source connection. The second lead of the first semiconductor package and the second lead of the second semiconductor package are arranged between the first semiconductor package and the second semiconductor package.

### TECHNICAL FIELD

The instant disclosure relates to semiconductor arrangements, in particular to Solid State circuit breakers, to systems including Solid State circuit breakers and to a corresponding manufacturing method.

### BACKGROUND

Solid State Circuit Breakers-SSCB (also referred to as Solid State Relays, SSRs) provide advanced protection for electrical systems by utilizing semiconductor technology and digital control.

SSCBs offer precise and rapid response to electrical faults like overcurrent, short circuits, and voltage fluctuations, safeguarding sensitive equipment. Unlike traditional circuit breakers, Solid State circuit breakers use semiconductor devices to interrupt the flow of current, allowing for faster and more accurate control. They often incorporate digital control systems for programmable protection settings and remote monitoring. Additionally, they can be integrated with energy storage systems, have advanced arc fault detection, and contribute to power quality improvement. Overall, Solid State circuit breakers represent a technological advancement in electrical protection, offering enhanced precision, control, and adaptability for modern power systems.

However, SSCBs are still difficult to manufacture.

Hence, there is a general need for SSCBs having decreased manufacturing effort.

### SUMMARY

According to a first aspect of the disclosure a semiconductor arrangement comprises a first semiconductor package and a second semiconductor package separate from the first semiconductor package, each semiconductor package comprising: a die carrier having a first main face and a second main face opposite to the first main face, a transistor die disposed on the first main face, a first lead connected to a first load electrode of the transistor die, a second lead connected to a gate electrode of the transistor die, an encapsulant embedding at least part of the first main face of the die carrier, inner portions of the leads and the transistor die, wherein the first lead of the first semiconductor package is electrically connected to the first lead of the second semiconductor package forming a source-source connection, and wherein the second lead of the first semiconductor package and the second lead of the second semiconductor package are arranged between the first semiconductor package and the second semiconductor package.

The semiconductor arrangements of the aforementioned kind are usually controlled by control circuitry, which is located overhead the semiconductor arrangement. Hence, the control circuitry needs to be contacted by connections of the semiconductor arrangement to enable a control current path to be established to the switches, that is transistor dies, of the semiconductor arrangement, which are usually located inside a mold compound. The switches of the semiconductor arrangement usually comprise gate pads, to receive a control current from the outside of the mold compound. For large-scale production, contacting the gate pads inside the mold compound requires additional process steps and is hence costly.

According to the present disclosure, costs are reduced by subdividing the semiconductor arrangement into two separate semiconductor packages. Both the first and the second semiconductor package may be a molded package. Hereafter, the terms molded package and semiconductor package may be used as synonyms. The semiconductor arrangement may hence be subdivided into a first molded package and a second molded package. The overall mold compound thus consists of two separate molded packages. Preferably a mold compound is used as an encapsulant, having a good Comparative Tracking Index (CTI) and a creeping resistance of at least 600 V.

By separating the mold compound into the first molded package and second molded package and arranging the first molded package and the second molded package substantially spaced apart from one another, it is possible that a contact lead, which is part of the control current path, may protrude out of each molded package in the space between the two molded packages. As a result, there is no need for costly process steps to contact the gate pads inside a mold compound, for example by drilling or etching.

Moreover, package warpage during production can be efficiently decreased by separating the first from the second molded package, as bigger packages face delamination problems over lifetime. Having two separate smaller semiconductor packages therefore increases the lifespan of the arrangement.

Further, the first leads which protrude out of each molded package are connected to one another to form a source-source connection between a first transistor die of the first semiconductor package and a second transistor die of the second semiconductor package. By connecting the source electrodes, which may be the first load electrodes, by the first leads, a bi-directional solid state circuit breaker may be formed having the advantages described above.

In an embodiment, an outer portion of the second lead protrudes vertically upward with respect to the first main face. The inner portion of the second leads may protrude horizontally outside of each of the first and the second molded package. An outer portion of the second leads may be bent upward to contact control circuitry overhead. Thereby, a simple way to implement a vertical connection to overhead circuitry is facilitated.

In an embodiment the first lead of the first semiconductor package and the first lead of the second semiconductor package form one integral part, which is exposed between the first semiconductor package and the second semiconductor package.

Particularly, a controllable load current path is formed between the die carrier of the first molded package and the die carrier of the second molded package via the first leads.

The integral part may be the source-source connection between each of the transistor dies. As a source-source connection is part of the load current path, it is advantageous that an integral part is formed, to carry high currents.

In an embodiment the outer portions of the second leads are configured to be connected to control circuitry, particularly to a gate driver. As the second leads may be part of control current path, they may be connected to a gate driver, which may be part of the control circuitry. As mentioned, the second leads contact possible gate pads of the inside semiconductor transistor dies in each of the molded packages.

In an embodiment at least a portion of the second main face of the die carrier is exposed to the outside of each molded package and forms a planar surface with a lowermost surface of the encapsulant. The molded packages may be formed by the encapsulant. The second main face of the die carrier may be part of the load current path, too.

The transistor die may be attached to a die pad which may be part of the die carrier. The die pad may be arranged at the first main face of the die carrier. That is, the transistor die may be disposed on the die pad at the first main face of the die carrier, preferably by diffusion soldering or soft soldering.

If the second main face of the die carrier is exposed to the outside, the exposed part may form a planar, flat surface through which a load current may flow. The lowermost surface of the encapsulant and the second main face of the die pad may be in the same plane. To enhance easy and safe connection to further load carrying elements, it is advantageous that the second main face of the die carrier and a lowermost surface of each molded package form a common, planar surface.

In an embodiment, the exposed part of the die carrier is a latch, a tab, a flap or a plate, protruding outward of the package body, and wherein the exposed part is configured to be attached to a busbar. All of the aforementioned connection elements are particularly apt to be safely and easily connected to, for example, a busbar.

The exposed part is configured to be attached to the busbar by one of laser welding, sintering, gluing, soldering, resistance welding, screwing or diffusion soldering. Having a latch as an embodiment of the exposed part of the die pad is particularly suitable for laser welding.

In an embodiment, a lateral dimension of the exposed part equals a lateral dimension of the busbar. The exposed part can be relatively broad with respect to the molded package and can thus carry high loads. Further, the exposed part can be as broad as the busbar. Thereby, an extensive, flat connection between the die pad and a busbar is facilitated, which is suitable for long-time high current applications.

The transistor die may be one of a vertical semiconductor transistor die, a semiconductor power transistor die, an IGBT die, a MOSFET die, a JFET die, a wide band gap semiconductor transistor die, in particular a SiC transistor die or a GaN transistor die.

Particularly, if the transistor die is a lateral GaN HEMT, the second lead is connected to a first gate electrode of the GaN HEMT, and each of the semiconductor packages comprises a third lead, which is connected to a second gate electrode of the GaN HEMT, and wherein the encapsulant embeds an inner portion of the second lead and the third lead and wherein an outer portion of the third lead protrudes vertically upward substantially parallel to the second lead.

Generally, lateral devices having more than one control connection are also conceived. More control leads can be included in each of the package accordingly.

The control leads, which are the second and third leads, may be substantially parallel, wherein the inner portion of the leads may be in the same plane, and also the outer portion of the leads, which extend vertically, may also be in the same plane. However, the control leads may also be arranged as required.

Particularly, the aforementioned embodiments of the semiconductor arrangements apply, if the semiconductor arrangement is a Solid State Circuit Breaker (SSCB) or a Solid State Relay (SSR), wherein the load current path is controllable via the second and/or third leads.

In an embodiment, a gate voltage is substantially within the same voltage domain as a source voltage. The term “voltage domain” may be referred to as a defined range or level of voltage within an electrical or electronic system. The source voltage may be about 230 V. The gate voltage may be about 18 V. Being in the same voltage domain, no isolation is required between the first and the second leads.

According to a second aspect of the present disclosure, a multiphase SSR is provided, the multiphase SSR comprising a plurality of semiconductor arrangements according to any of the preceding aspects and embodiments, wherein the semiconductor arrangements may be connected in parallel. The semiconductor arrangements may also just be arranged in parallel and remain electrically and/or logically isolated from one another.

According to a third aspect of the disclosure, a system is provided comprising the semiconductor arrangement of the first or the multiphase SSR of the second aspect and a busbar.

In an embodiment of the third aspect, the system further comprises control circuitry, particularly a gate driver. Further, the system may comprise sensing elements for sensing current events. The sensing elements may be configured to provide sense signals to the control circuitry. The control circuitry controls the gate current of the transistor dies of the semiconductor arrangement to enable or interrupt a load current flow via the load current path of the semiconductor arrangement.

In a fourth aspect of the present disclosure, a method for manufacturing a semiconductor arrangement is provided, the method comprising: Providing a first semiconductor package and a second semiconductor package separate from the first semiconductor package, wherein manufacturing each semiconductor package comprises: Providing a die carrier having a first main face and a second main face opposite to the first main face; Disposing a transistor die on the first main face; Connecting a first lead to a first load electrode of the transistor die; Connecting a second lead to a gate electrode of the transistor die; Embedding, by an encapsulant, at least part of the first main face of the die carrier, inner portions of the leads and the transistor die; and Forming a source-source connection by electrically connecting the first lead of the first molded package to the first lead of the second molded package; and arranging the second lead of the first molded package and the second lead of the second molded package between the first molded package and the second molded package.

In an embodiment of the fourth aspect, the method comprises arranging an outer portion of the second lead to protrude vertically upward with respect to the first main face.

### BRIEF DESCRIPTION OF THE DRAWINGS

FIG. 1 is a schematic cross-sectional view of a semiconductor arrangement.

FIG. 2 schematically illustrates a 3-D view of a semiconductor arrangement.

FIG. 3 schematically illustrates a 3-D view of a semiconductor arrangement without encapsulant.

FIG. 4 illustrates a side view of a semiconductor arrangement without encapsulant.

FIGS. 5A and 5B schematically illustrate a top view and a bottom view of a semiconductor arrangement according to further embodiments of the disclosure.

FIG. 6 is multichannel SSCB/SSR.

FIG. 7 is a further embodiment including a lateral transistor die.

FIG. 8 is a flow diagram of some aspects of the method according to the disclosure.

### DETAILED DESCRIPTION

In the following detailed description, reference is made to the accompanying drawings. The drawings show specific examples in which the invention may be practiced. It is to be understood that the features and principles described with respect to the various examples may be combined with each other, unless specifically noted otherwise. As well as in the claims, designations of certain elements as “first element”, “second element”, “third element” etc. are not to be understood as enumerative. Instead, such designations serve solely to address different “elements”. That is, e.g., the existence of a “third element” does not require the existence of a “first element” and a “second element”. An electrical line as described herein may be a single electrically conductive element or include at least two individual electrically conductive elements connected in series and/or parallel. Electrical lines may include metal and/or semiconductor material, and may be permanently electrically conductive (i.e., non-switchable). An electrical line may have an electrical resistivity that is independent from the direction of a current flowing through it. A semiconductor body as described herein may be made of (doped) semiconductor material and may be a semiconductor chip or be included in a semiconductor chip. A semiconductor body has electrically connected pads and includes at least one semiconductor element with electrodes. The pads are electrically connected to the electrodes which includes that the pads are the electrodes and vice versa.

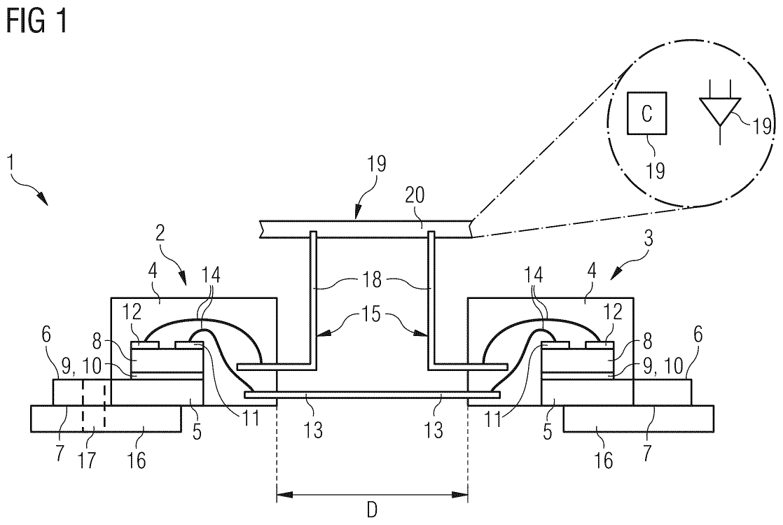

Referring to FIG. 1, a semiconductor arrangement 1 according to the present disclosure is shown. The semiconductor arrangement 1 comprises a first molded package 2 and a second molded package 3. Both the first molded package 2 and the second molded package 3 can be referred to as a package body. The first molded package 2 is spaced apart from the second molded package 3. Each of the first molded package 2 and the second molded package 3 is formed by an encapsulant 4. The encapsulant 4 may also be referred to as a mold compound.

Each of the first molded package 2 and the second molded package 3 comprises a die carrier 5. The die carrier 5 comprises a first main face 6, which may be referred to as an upper main face. The die carrier 5 comprises a second main face 7 opposite the first main face 6. Both the first main face 6 and the second main face 7 may be located in planes, which are substantially parallel to one another. In each package 2, 3, a transistor die 8 is disposed on the first main face 6 of the die carrier 5. The transistor die 8 is attached to the die carrier 5 by a layer structure 9, which may be formed by an electrically conductive die attach adhesive. Preferably, a “green” die attach adhesive, like a polymer compound may be used.

A bottom side of the transistor die 8 forms a second load electrode 10 of the die 8, which is, by the layer structure 9, electrically connected to the die carrier 5. Further, each transistor die 8 comprises a first load electrode 11 and a gate electrode 12. The first load electrode 11 is connected to a first lead 13, by bonding wires 14. The gate electrode 12 is also connected by bonding wires 14 to a second lead 15.

The encapsulant 4 embeds at least part of the die carrier 5, the transistor die 8, and inner portions of the first and second lead 13, 15. The second main face 7 of the die carrier 5 and a lowermost surface of the encapsulant 4 form a common planar surface which is in the same plane, as the second main face 7, and which is substantially parallel to the first main face 6. A lowermost portion of the die carrier 5, that is, a lowermost surface of the die carrier 5 is not covered by the encapsulant 4 but exposed from the package body 2, 3.

A portion of the die carrier 5 protrudes laterally out of each package body 2, 3. The lowermost exposed portion of the die carrier 5 is attached to at least one busbar 16. The die carrier 5 can be attached to the busbar 16 for example by way of screwing. Therefore, each die carrier 5 may have at least one screw hole 17.

The inner portion of the first and second leads 13, 15 protrudes out of the package body 2, 3. The first lead 13 of each of the first molded package 2 and the second molded package 3 are electrically connected to one another. The electrically connected first leads 13 form an electrical connection between both the first load electrode 11 of the first molded package 2 and the first load electrode 11 of the second molded package 3. The first leads 13 may form a source-source connection.

The first leads 13 are not completely covered by the encapsulant 4 but are exposed in the space between the package bodies 2,3.

The second leads 15, which are connected to the gate electrode 12 of each transistor die 8 also protrude out of the encapsulant 4. Unlike the first leads 13, the second leads 15 have a vertical portion 18, which protrudes vertically upward with respect to the first main face 6 of the die carrier 5. For example, the second leads 15 can be bent upward before or after a molding step. The second lead 15 of the first molded package 2 and the second lead of the second molded package 3 are arranged in the same space as the first lead 13, namely between the package bodies 2, 3. The second leads 15 are arranged in between the first molded package 2 and the second molded package 3.

The second leads 15 which can also be referred to as gate leads or control leads, are attached to a control device 19. Control device 19 can be a microcontroller, an analogue control circuit, a digital control circuit or a comparator. The control device 19 may also include or be arranged at a printed circuit board (PCB) 20. The second leads 15 may protrude through the PCB 20, and may be attached to the PCB 20 by, for example, by wave soldering.

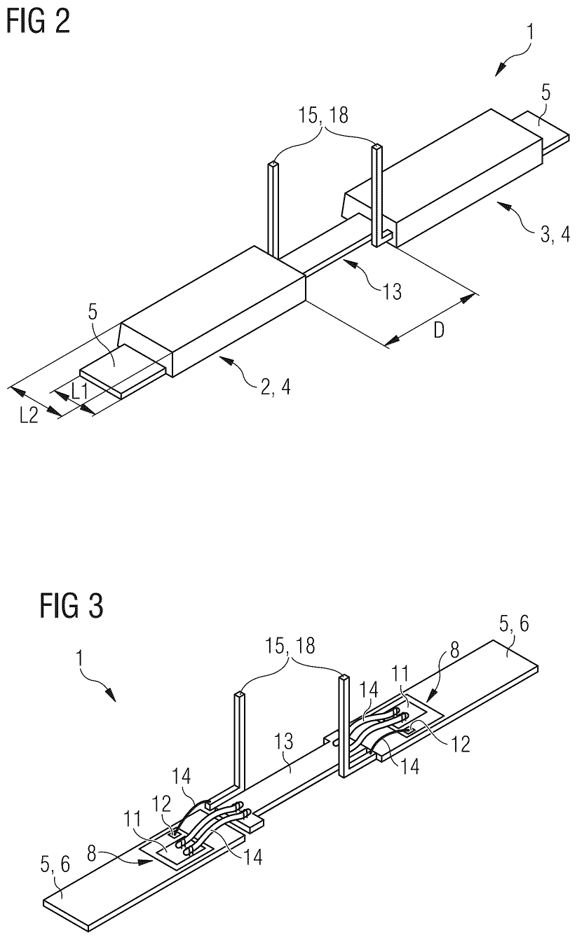

FIG. 2 schematically illustrates a 3-D view of a semiconductor arrangement 1. The semiconductor arrangement 1 is a solid-state circuit breaker (SSBC) or a Solid State Relay (SSR). The semiconductor arrangement 1 comprises two mold bodies 2,3 consisting of encapsulant 4. Horizontal portions of the die carrier 5 protrude out of the package body forming an electrical interconnect to further devices (not shown). The horizontal portions 5 are configured to be attached to, for example, a busbar 16 by one of laser welding, sintering, soldering, resistance welding, screwing, conductive glueing, press-fitting or diffusion soldering.

The package bodies 2, 3 are spaced apart from one another by a distance D, (see also FIG. 1). The distance D is a safe distance and can be in the range of 4 mm upwards, depending on a voltage in a load current path. The package bodies 2, 3 are connected by the first leads 13. The first leads 13 of the first molded package 2 and the second molded package 3 are one integral part. The vertical portions 18 of the second leads 15 are bent upward and are arranged in the space between the package bodies 2, 3.

A lateral dimension L1 of the horizontal portions of the die carrier 5 is about 80% of a lateral dimension L2 of the mold body 2, 3.

FIG. 3 schematically illustrates a 3-D view of a semiconductor arrangement 1 without encapsulant 4, thereby exposing an inner structure of the semiconductor arrangement 1. The first lead 13, which is formed by an integral part, is double L shaped.

A load current path is defined between the die carrier 5 of the first molded package 2 and the die carrier 5 of the second molded package 3. A control current path is defined between the second leads 15 via the wire bonds 14 to the gate electrode 12 and the first load electrode 11 of the transistor die 8. The load current path is controllable by the control current path. A voltage difference between the control the voltage in the load current path and the source voltage in the load current path is at most 18 V. Thereby, the gate voltage and the load voltage at the first load electrode 11 are substantially within the same voltage domain. As a result, no additional insulation is required between the first lead 13 and the second lead 15.

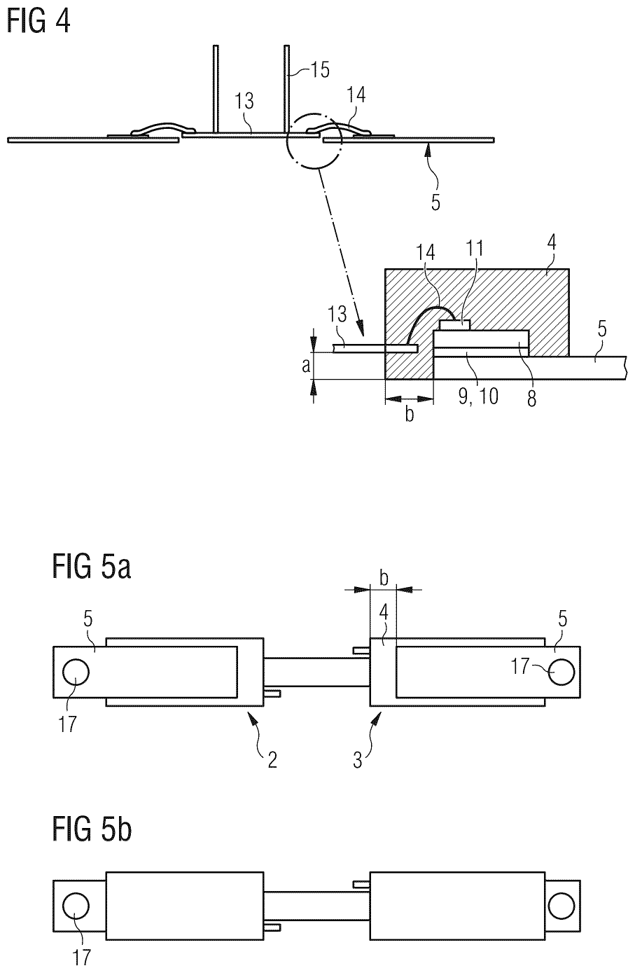

FIG. 4 illustrates a side view of a semiconductor arrangement 1 without encapsulant 4. The first leads 13 are spaced apart from the lowermost surface of the encapsulant 4 by a distance a.

As can be seen in the extension view of FIG. 4, thereby, a creepage distance between the exposed part of the die carrier 5 and the first lead 13 is enlarged. To elaborate, the creepage distance starts at the lowermost surface of the die carrier 5, which forms a planar surface with the lowermost surface of the encapsulant and ends at the first lead 13. The creepage distance consist of distance a and distance b and is the distance along the outer surface of the encapsulant 4. Distance b equals the lateral extension of the lowermost surface of the encapsulant 4.

FIGS. 5A and 5B schematically illustrate a top view (FIG. 5A) and a bottom view (FIG. 5B) of a semiconductor arrangement 1 according to further embodiments of the disclosure.

In the bottom side view of FIG. 5A it can be seen that the exposed portion of the die carrier 5 is large in comparison to the overall lowermost surface of the molded package 2, 3. The exposed portion of the die carrier 5 covers around 80% of the entire lowermost surface of each molded package 2,3. The exposed portion of the die carrier 5 is exposed, that is, not covered by the encapsulant 4. Distance b is the distance from the exposed portion of the die carrier along the lowermost surface of the encapsulant 4. Thereby, a flat two-dimensional connection between the die carrier 5 and for example a busbar 16 (not shown) is possible which enables high load currents.

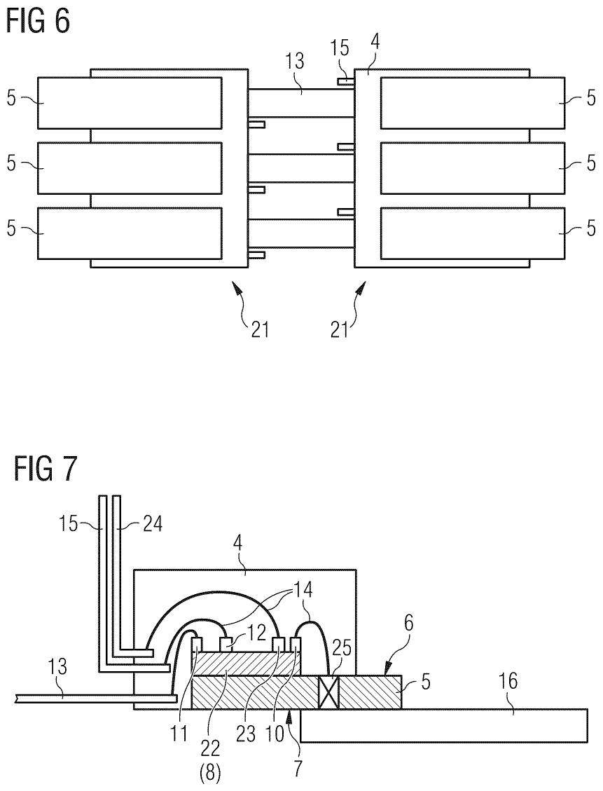

FIG. 6 is a multichannel Solid State Circuit Breaker (SSCB) or Solid State Relay (SSR) comprising three semiconductor arrangements 1. Each side of each semiconductor arrangement 1 share a common molded body 21. That is, each of the first molded package 2 and the second molded package 3 comprises a plurality of die carriers 5, a plurality of first and second leads 13,15, and wherein each die carrier 5 of the plurality of die carriers 5 carries a transistor die 8. Thereby, multiple connections, that is, multiple load currents, are formed. The die carriers 5 of each side share a common mold body 21. Each semiconductor arrangement 1 of the parallel semiconductor arrangements forms one channel, that is, a controllable load path. Each load path may be controllable separately, or all of the load paths may be controllable by a common controller/gate driver (not shown), which may be connected to each of the second leads 15 or to the plurality of the second leads 15.

FIG. 7 is a further embodiment including a lateral transistor die 22. The lateral transistor die 22 may be a GaN HEMT having a first gate electrode 12 an additional gate electrode 23. First gate electrode and additional gate electrode 23 may be controlled by gate voltages which are different from one another. The lateral transistor die 22 comprises a first load electrode 11 and a second load electrode 10. The first load electrode 11 is connected to the first lead 13, as shown in the above-described figures. The first gate electrode 12 is connected to the second lead 15 as described above. As a gate voltage of the additional gate electrode 23 is different from the gate voltage of the first gate electrode 12, the additional gate electrode 23 is connected to an additional second lead 24, which may also be referred to as a third lead.

The additional lead 24 may be substantially parallel to the second lead 15. That is, the first portions on the second lead 15 and the first portions of the additional lead 24 which are embedded in the encapsulant 4, may be in the same plane or may be staggered. The additional lead 24 can be bent upward towards and have a vertical portion 18, too. As the second lead 15, the additional second lead 24 may be configured to be connected to a control device 19 (not shown). More additional second leads 24 are possible if more control connections to the inside of the encapsulant 4 are needed.

The lateral transistor die 22 is arranged on a substrate, which may provide the functionality of the die carrier 5. The substrate may be a DCB or an AMB. The second load electrode 10 of the lateral transistor die 22 is connected, by bonding wires 14, to an interconnect 25. The interconnect 25 may be a Trough Silicon Via (TSV) or a plated through hole. Interconnect 25 provides an electrical connection through the substrate to connect the second load electrode 10 to the busbar 16.

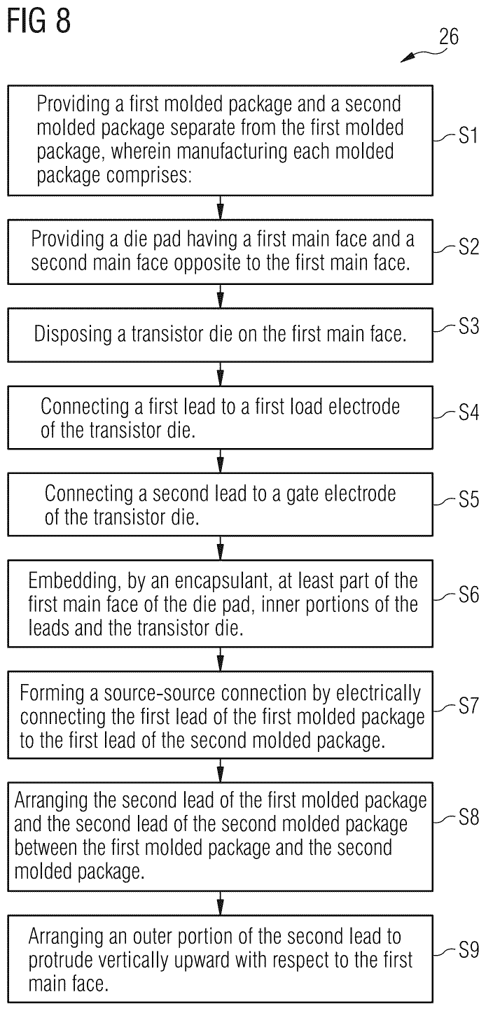

FIG. 8 is a flow diagram of some aspects of a method 26 for manufacturing a semiconductor arrangement 1 according to the disclosure.

In step S1 a first molded package and a second molded package separate from the first molded package are provided. Manufacturing each molded package comprises the following steps:

In step S2 a die carrier having a first main face and a second main face opposite to the first main face are provided.

In step S3 a transistor die is disposed on the first main face.

In step S4 a first lead is connected to a first load electrode of the transistor die.

In step S5 a second lead is connected to a gate electrode of the transistor die.

In step S6 at least part of the first main face of the die carrier, inner portions of the leads and the transistor die are embedded by an encapsulant.

In step S7 a source-source connection is formed by electrically connecting the first lead of the first molded package to the first lead of the second molded package.

In Step S8 the second lead of the first molded package and the second lead of the second molded package are arranged between the first molded package and the second molded package.

Additionally, method 26 may comprise step S9, which comprises arranging an outer portion of the second lead to protrude vertically upward with respect to the first main face.

### LIST OF REFERENCE SIGNS

1 Semiconductor arrangement
2 first molded package
3 second molded package
4 encapsulant
5 die carrier
6 first main face
7 second main face
8 transistor die
9 layer structure
10 second load electrode
11 first load electrode
12 gate electrode
13 first lead
14 bonding wires
15 second lead
16 busbar
17 screw hole
18 vertical portion of the second leads
19 control device
20 PCB
21 Common mold body
22 Lateral transistor die
23 Additional gate electrode
24 Additional second lead/third lead
25 Interconnect
26 Method

What is claimed is:

1. A semiconductor arrangement, comprising:
a first semiconductor package and a second semiconductor package separate from one another, each semiconductor package comprising:
a die carrier having a first main face and a second main face opposite to the first main face;
a transistor die disposed on the first main face;
a first lead connected to a first load electrode of the transistor die;
a second lead connected to a gate electrode of the transistor die; and
an encapsulant embedding at least part of the first main face of the die carrier, inner portions of the leads and the transistor die,
wherein the first lead of the first semiconductor package is electrically connected to the first lead of the second semiconductor package, forming a source-source connection,
wherein the second lead of the first semiconductor package and the second lead of the second semiconductor package are arranged between the first semiconductor package and the second semiconductor package.

2. The semiconductor arrangement of claim 1, wherein an outer portion of the second lead of each semiconductor package protrudes vertically upward with respect to the first main face.

3. The semiconductor arrangement of claim 1, wherein the first lead of the first semiconductor package and the first lead of the second semiconductor package form one integral part, which is exposed between the first semiconductor package and the second semiconductor package.

4. The semiconductor arrangement of claim 1, wherein outer portions of the second leads are configured to be connected to a gate driver.

5. The semiconductor arrangement of claim 1, wherein at least a portion of the second main face of the die carrier is exposed to an outside of each semiconductor package and forms a planar surface with a lowermost surface of the encapsulant.

6. The semiconductor arrangement of claim 5, wherein the exposed part of the die carrier is a latch, a tab, a flap or a plate, protruding outward of the package body, and wherein the exposed part is configured to be attached to a busbar.

7. The semiconductor arrangement of claim 6, wherein the exposed part is configured to be attached to the busbar by one of laser welding, sintering, gluing, soldering, resistance welding, screwing or diffusion soldering.

8. The semiconductor arrangement of claim 6, wherein a lateral dimension of the exposed part equals a lateral dimension of the busbar.

9. The semiconductor arrangement of claim 1, wherein a controllable load current path is formed between the die carrier of the first semiconductor package and the die carrier of the second semiconductor package via the first leads.

10. The semiconductor arrangement of claim 1, wherein the transistor die of each semiconductor package is one of a vertical semiconductor transistor die, a semiconductor power transistor die, an IGBT die, a MOSFET die, a JFET die, a wide band gap semiconductor transistor die.

11. The semiconductor arrangement of claim 1, wherein the transistor die of each semiconductor package is a lateral GaN HEMT, the second lead is connected to a first gate electrode of the lateral GaN HEMT, and each of the semiconductor packages comprises a third lead, which is connected to a second gate electrode of the lateral GaN HEMT, wherein the encapsulant embeds an inner portion of the second lead and the third lead, and wherein an outer portion of the third lead protrudes vertically upward substantially parallel to the second lead.

12. The semiconductor arrangement of claim 1, wherein the semiconductor arrangement is a solid state relay, and wherein the load current path is controllable via the second lead and/or a third lead.

13. The semiconductor arrangement of claim 1, wherein a gate voltage is substantially within a same voltage domain as a source voltage.

14. A multiphase SSR comprising a plurality of semiconductor arrangements of claim 1, connected in parallel.

15. A system comprising the semiconductor arrangement of claim 1 and a busbar.

16. The system of claim 15, further comprising a gate driver.

17. A method for manufacturing a semiconductor arrangement, the method comprising:
providing a first semiconductor package and a second semiconductor package separate from one another, wherein providing each semiconductor package comprises:
providing a die carrier having a first main face and a second main face opposite to the first main face;
disposing a transistor die on the first main face;
connecting a first lead to a first load electrode of the transistor die;
connecting a second lead to a gate electrode of the transistor die;
embedding, by an encapsulant, at least part of the first main face of the die carrier, inner portions of the leads and the transistor die; and
forming a source-source connection by electrically connecting the first lead of the first semiconductor package to the first lead of the second semiconductor package; and
arranging the second lead of the first semiconductor package and the second lead of the second semiconductor package between the first semiconductor package and the second semiconductor package.

18. The method of claim 17, further comprising arranging an outer portion of the second lead to protrude vertically upward with respect to the first main face.
